(19) United States
(12) Patent Application Publication
(10) Pub. No.: US 2012/0139060 A1
(43) Pub. Date: Jun. 7, 2012

(54) SEMICONDUCTOR DEVICE HAVING GUARD RING

(75) Inventors: Sang-hyeon JEON, Suwon-si (KR); Jun-yong NOH, Yongin-si (KR); Bong-gu SUNG, Seoul (KR)

(73) Assignee: SAMSUSNG ELECTRONICS CO., LTD.,, Suwon-si (KR)

(21) Appl. No.: 13/370,819

(22) Filed: Feb. 10, 2012

Related U.S. Application Data
(62) Division of application No. 12/314,830, filed on Dec. 17, 2008.

(30) Foreign Application Priority Data
Jan. 3, 2008 (KR) 10-2008-0000704

(51) Int. Cl. H01L 29/78

(52) U.S. Cl. 257/409; 257/E29.255

(57) ABSTRACT

A semiconductor device includes an internal circuit region on a semiconductor substrate, at least one guard ring on the semiconductor substrate, the guard ring surrounding the internal circuit region, and at least one current blocking unit on the semiconductor substrate, the current blocking unit being configured to block an electric current flowing from the guard ring to the semiconductor substrate.

### CROSS REFERENCE TO RELATED APPLICATION

This is a divisional application based on pending application Ser. No. 12/314,830, filed Dec. 17, 2008, the entire contents of which is hereby incorporated by reference.

### BACKGROUND OF THE INVENTION

1. Field of the Invention

Example embodiments relate to a semiconductor device. More particularly, example embodiments relate to a semiconductor device with a guard ring.

2. Description of the Related Art

A conventional semiconductor device may include an internal circuit region and a guard ring surrounding the internal circuit region, so moisture and/or particles in the air may have minimized contact with the internal circuit. For example, the guard ring may prevent moisture in the air from percolating into the internal circuit region.

As an integration degree of the semiconductor device increases, a gap between the internal circuit region and the guard ring may be reduced, thereby causing bridging between the internal circuit region and the guard ring. Bridging between the internal circuit region and the guard ring may cause voltage drop in the internal circuit region via the guard ring, so operability and reliability of the semiconductor device may be reduced.

### SUMMARY OF THE INVENTION

Example embodiments are therefore directed to a semiconductor device with a ring guard, which substantially overcomes one or more of the disadvantages of the related art.

It is therefore a feature of an example embodiment to provide a semiconductor device with a ring guard capable of preventing voltage drop in an internal circuit of the semiconductor device, when the internal circuit region and the guard ring are bridged.

At least one of the above and other features and advantages may be realized by providing a semiconductor device, including an internal circuit region on a semiconductor substrate, at least one guard ring on the semiconductor substrate, the guard ring surrounding the internal circuit region, and at least one current blocking unit on the semiconductor substrate, the current blocking unit being configured to block an electric current flowing from the guard ring to the semiconductor substrate. The guard ring may include at least one conductive layer in an interlayer insulating layer, the interlayer insulating layer being on the semiconductor substrate. The guard ring may be positioned along edges of the semiconductor substrate to surround an entire perimeter of the internal circuit region. The current blocking unit may be electrically connected to the guard ring, the current blocking unit being between the guard ring and the semiconductor substrate.

The current blocking unit may be a reverse junction region on the semiconductor substrate. The reverse junction region may include a p-well region on the semiconductor substrate, and a n-type impurity region on the p-well region. The current blocking unit may be a gate stack on the semiconductor substrate. The gate stack may include a gate insulation layer on the semiconductor substrate, and a gate electrode on the gate insulation layer. The gate insulation layer may be in a recess channel trench of the semiconductor substrate. The semiconductor device may further include a dicing region surrounding the guard ring. The semiconductor device may further include a plurality of guard rings and current blocking units, at least one interlayer insulating layer being positioned between adjacent guard rings, each guard ring being connected to a separate current blocking unit.

The semiconductor device may further include a p-well region in the semiconductor substrate, the internal circuit region on the p-well region, the internal circuit including a transistor in a first region of the p-well region, and an internal routing layer in an interlayer insulating layer, the interlayer insulating layer being on the transistor, a n-type impurity region in a second region of the p-well region, the n-type impurity region and the p-well region defining the current blocking unit, and the guard ring on the second region of the p-well region, the guard ring including a conductive plug and a guard routing layer on the n-type impurity region. The semiconductor substrate may be a p-type semiconductor substrate. The internal circuit region may include a transistor in a n-well region on the semiconductor substrate, the first region of the p-well region being between the n-well region and the second region of the p-well region. The semiconductor device, wherein the internal circuit may include a transistor in a first region of the semiconductor substrate, at least one interlayer insulating layer on the transistor, and an internal routing layer in the at least one interlayer insulating layer, the current blocking unit includes a gate stack in a second region of the semiconductor substrate, the gate stack surrounding the internal circuit region, and the guard ring may include the interlayer insulating layer on the gate stack, a guard routing layer in the interlayer insulating layer, the guard routing layer being connected to the gate stack, and a conductive plug between the guard routing layer and the gate stack. The gate stack may include a gate insulation layer on the semiconductor substrate, and a gate electrode on the gate insulation layer. The gate insulation layer may be in a recess channel trench of the semiconductor substrate.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of a semiconductor device according to an example embodiment;

FIG. 2 illustrates a cross-sectional view along line II-II of FIG. 1;

FIG. 3 illustrates a cross-section view of a semiconductor device according to another example embodiment;

FIG. 4 illustrates a cross-sectional view of a semiconductor device according to another example embodiment; and

FIG. 5 illustrates a magnified view of a gate stack of FIG. 4.

### DETAILED DESCRIPTION OF THE INVENTION

Korean Patent Application No. 10-2008-0000704, filed on Jan. 3, 2008, in the Korean Intellectual Property Office and entitled: “Semiconductor Device Having Guard Ring,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of elements, layers, and regions may be exaggerated for clarity of illustration. It will also be understood that when an element and/or layer is referred to as being “on” another element, layer and/or substrate, it can be directly on the other element, layer, and/or substrate, or intervening elements and/or layers may also be present. Further, it will be understood that the term “on” can indicate a vertical arrangement of one element and/or layer with respect to another element and/or layer, and may not indicate a vertical orientation, e.g., a horizontal orientation. In addition, it will also be understood that when an element and/or layer is referred to as being “between” two elements and/or layers, it can be the only element and/or layer between the two elements and/or layers, or one or more intervening elements and/or layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of:” For example, the expression “at least one of A, B, and C” may also include an nth member, where n is greater than 3, whereas the expression “at least one selected from the group consisting of A, B, and C” does not.

As used herein, the terms “a” and “an” are open terms that may be used in conjunction with singular items or with plural items.

A semiconductor device according to an example embodiment may include an internal circuit region, a protective part at the outer edge or perimeter of the internal circuit region, and a current blocking unit. The protective part may protect the internal circuit region of the semiconductor device from moisture or particles, e.g., ions, in the air. The protective part of the semiconductor device may surround the internal circuit region. The protective part may be formed while the internal circuit is being formed, e.g., the protective part and the internal circuit may be formed in a substantially same process. For example, the protective part may have a general form of a square ring, a circular ring, or the like. It is noted that, hereinafter, the protective part may be used interchangeably with a “guard ring” or a “seal ring.”

The guard ring may isolate the internal circuit region from the effects of moisture or ions. The guard ring may also prevent formation of cracks on an interlayer insulating layer of the internal circuit region during dicing, i.e., when a semiconductor wafer may be diced along a dicing region to divide the semiconductor wafer into a plurality of semiconductor devices, e.g., semiconductor chips. It is noted that the dicing region may also be referred to as a scribe line region.

The current blocking unit of the semiconductor device may be connected to the guard ring, and may be capable of blocking a flow path of an electric current, e.g., a path of electric current flowing from the internal circuit region through the guard ring into a substrate. For example, even if the internal circuit region is bridged with the guard ring, an electric current flowing out from the internal circuit region and through the guard ring may be blocked by the current blocking unit, so voltage drop in the internal circuit region of the semiconductor device, i.e., caused by current flow out of the internal circuit region through the guard ring into the substrate, may be prevented or substantially minimized.

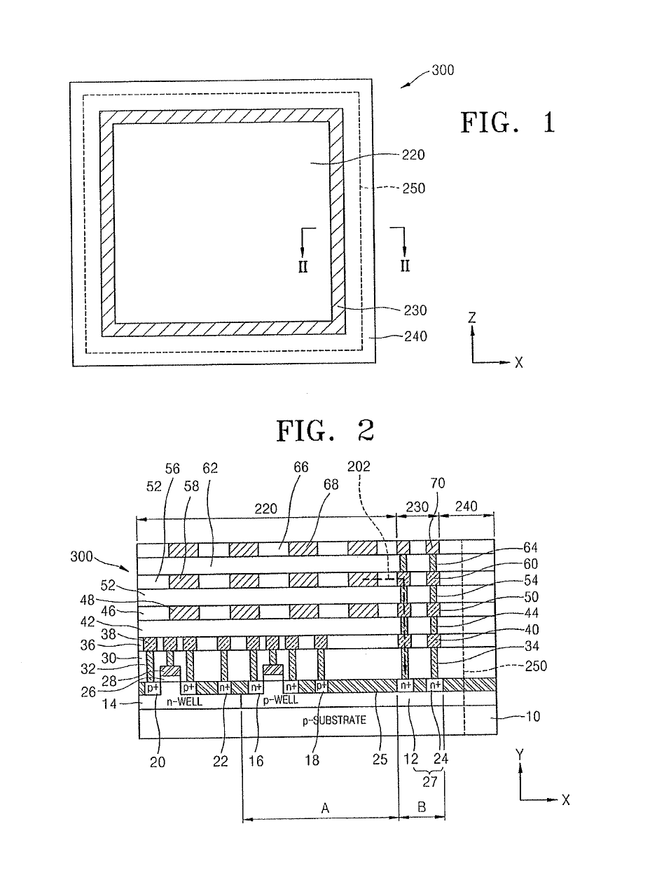

A semiconductor device according to an example embodiment will now be described more fully with reference to FIGS. 1-2. FIG. 1 illustrates a plan view of a semiconductor device 300 with a guard ring 230 according to an example embodiment, and FIG. 2 illustrates a cross-sectional view along lines II-II of FIG. 1.

Referring to FIGS. 1 and 2, the semiconductor device 300 may include a semiconductor substrate 10, an internal circuit region 220 on the semiconductor substrate 10, the guard ring 230 on the semiconductor substrate 10 and surrounding the internal circuit region 220, and a current blocking unit 27. The semiconductor substrate 10 may be any suitable semiconductor substrate, e.g., a p-type silicon substrate.

The internal circuit region 220 may include an integrated circuit. For example, the internal circuit region 220 may include a transistor, e.g., a metal-oxide semiconductor (MOS) transistor, a word line for driving the transistor, a bit line, and internal routing layers. For example, the internal circuit region 220 may include a gate electrode 28, i.e., a word line, and first through fourth internal routing layer 38, 48, 58, and 68. The gate electrode 28 may be, e.g., a poly-silicon layer doped with impurities. The first internal routing layer 38 may be, e.g., a bit line. The first through fourth internal routing layers 38, 48, 58, and 68 may be, e.g., metal layers.

More particularly, the internal circuit region 220 may include a p-well region 12 and a n-well region 14 on the semiconductor substrate 10. A n-type MOS transistor may be formed on a first region A of the p-well region 12 and a p-type MOS transistor may be formed on the n-well region 14, so a complementary MOS (CMOS) transistor may be formed in the first region A of the p-well region 12 and in the n-well region 14. The first region A of the p-well region 12 may be adjacent to the n-well region 14, e.g., the first region A of the p-well region 12 may be in direct contact with the n-well region 14.

The n-type MOS transistor may include a gate insulation layer 26 on the semiconductor substrate 10, the gate electrode 28 on the gate insulation layer 26, and a n⁺ impurity region 16 in the semiconductor substrate 10 on each side of the gate insulation layer 26. A p⁺ impurity region 18 may also be formed in the first region A of the p-well region 12. The p-well region 12 may be floated when the semiconductor device is in operation. The p-type MOS transistor may include the gate insulation layer 26 on the semiconductor substrate 10, the gate electrode 28 on the gate insulation layer 26, and a p⁺ impurity region 20 in the semiconductor substrate 10 on each side of the gate insulation layer 26. A n⁺ impurity region 22 may also be formed in the n-well region 14. The p⁺ and n⁺ impurity regions 20 and 22 in the n-well region 14 may be insulated from each other by a device isolating layer 25. Similarly, the n⁺ and p⁺ impurity regions 16 and 18 in the p-well region 12 and the p⁺ impurity region 20 in the n-well region 14 may be insulated from each other by the device isolating layer 25.

As illustrated in FIG. 2, the internal circuit region 220 may further include internal circuit conductive plugs 32 connected to each of the gate electrodes 28, the n⁺ and p⁺ impurity regions 16 and 18 in the p-well region 12, and the p⁺ and n⁺ impurity regions 20 and 22 in the n-well region 14. The internal circuit conductive plugs 32 may be insulated from each other by a first interlayer insulating layer 30.

As illustrated in FIG. 2, the internal circuit region 220 may further include the first internal routing layer 38 connected to the internal circuit conductive plugs 32. For example, as further illustrated in FIG. 2, each portion of the first internal routing layer 38 may be positioned on, e.g., directly on, a respective internal circuit conductive plug 32. The portions of the first internal routing layer 38 may be spaced apart from each other along a horizontal direction, and may be insulated from each other by a second interlayer insulating layer 36. For example, the first internal routing layer 38 may be connected to the n⁺ impurity region 16 in the p-well region 12 and to the p⁺ impurity region 20 in the n-well region 14 to function as a bit line.

As illustrated in FIG. 2, the internal circuit region 220 may further include third through eighth interlayer insulating layers 42, 46, 52, 56, 62, and 66. The third through eighth interlayer insulating layers 42, 46, 52, 56, 62, and 66 may be sequentially formed on the first internal routing layer 38. The second internal routing layer 48, the third internal routing layer 58, and the fourth internal routing layer 68 may be formed in the fourth, sixth, and eighth interlayer insulating layers 46, 56, and 66, respectively, as further illustrated in FIG. 2. For example, the third, fifth, and seventh interlayer insulating layers 42, 52, and 62 may be continuously formed to cover an underlying layer. The fourth, sixth, and eighth interlayer insulating layers 46, 56, and 66 may be include a plurality of discrete portions along the horizontal direction, so each portion may insulate adjacent portions of a respective routing layer. For example, as illustrated in FIG. 2, a portion of the third internal routing layer 58 may be between the fifth and seventh interlayer insulating layers 52 and 62 along a vertical direction, e.g., along the y-axis, and may be between adjacent portions of the sixth interlayer insulating layer 56 along the horizontal direction, e.g., along the x-axis. The interlayer insulating layers 30, 36, 42, 46, 52, 56, 62, and 66 may be oxide layers.

It is noted that the internal circuit region 220 may not be limited to the elements and configuration illustrated in FIG. 2 and may include any suitable configuration of elements. For example, the internal circuit region 220 may include only the n-type MOS transistor, only the p-type MOS transistor, additional internal routing layers, smaller number of routing layers, one of the internal routing layers may be used as a power line for applying power voltage of a few volts, and so forth.

The guard ring 230 of the semiconductor device 300 may surround the internal circuit region 220, e.g., surround an entire perimeter of the internal circuit region 220. For example, the guard ring 230 may be continuous along edges of the semiconductor device 300, i.e., to surround an entire perimeter of a semiconductor chip, on the semiconductor substrate 10. The guard ring 230 may be formed to protect the internal circuit region 220 from the effects of moisture or ions in the air, e.g., effects of moisture in the air.

As illustrated in FIG. 2, the guard ring 230 may include first through fourth guard routing layers 40, 50, 60 and 70, and corresponding first through fourth conductive plugs 34, 44, 54 and 64. For example, as illustrated in FIG. 2, the first through fourth guard routing layers 40, 50, 60 and 70, and the first through fourth conductive plugs 34, 44, 54 and 64 may be alternately arranged on top of each other along the vertical direction. The first through fourth guard routing layers 40, 50, 60, and 70 and the first through the fourth conductive plugs 34, 44, 54, and 64 may be metal layers. The first through fourth guard routing layers 40, 50, 60 and 70, and the first through fourth conductive plugs 34, 44, 54 and 64 may be electrically connected to each other, so, e.g., an electrical path may be formed from the fourth guard routing layer 70 toward the first conductive plug 34, as illustrated in FIG. 2.

The first through fourth guard routing layers 40, 50, 60 and 70, and the first through fourth conductive plugs 34, 44, 54 and 64 of the guard ring 230 may be formed in the interlayer insulating layers 36, 46, 56, 66, 32, 42, 52, and 62, respectively. For example, the fourth guard routing layer 40 may be formed in the second interlayer insulating layer 36, so upper surfaces of the fourth guard routing layer 40, second interlayer insulating layer 36, and internal routing layer 38 may be substantially coplanar. Similarly, lower surfaces of the fourth guard routing layer 40, second interlayer insulating layer 36, and internal routing layer 38 may be substantially coplanar.

The guard ring 230 may be formed on a second region B of the p-well region 12 on the semiconductor substrate 10, so the guard ring 230 and the internal circuit region 220 may be positioned on the p-well region 12. In this respect, it is noted that the first and second regions A and B of the p-well region 12 may be adjacent to each other, i.e., the first region A of the p-well region 12 may be between the second region B of the p-well region 12 and the n-well region 14, and may be integral with each other.

The semiconductor device 300 may include a plurality of guard rings 230. For example, as illustrated in FIG. 2, the semiconductor device 300 may include two guard rings 230, so each of the guard rings 230 may include the first through fourth guard routing layers 40, 50, 60 and 70 with the corresponding first through fourth conductive plugs 34, 44, 54 and 64. As further illustrated in FIG. 2, the two guard rings 230 may be spaced apart from each other along the horizontal direction, and a stacked structured of the interlayer insulating layers 30, 36, 42, 46, 52, 56, 62, and 66 may be positioned therebetween.

The current blocking unit 27 of the semiconductor device 300 may include a n⁺ type impurity region 24 in the second region B of the p-well region 12, and may be connected, e.g., directly connected, to the guard ring 230. For example, the first conductive plug 34 of the guard ring 230 may be positioned on, e.g., directly on, the n⁺ type impurity region 24. The n⁺ type impurity region 24 may be spaced apart from the p⁺ impurity region 18 in the first region of the p-well region 12 along the horizontal direction, and may be insulated from the p⁺ impurity region 18 by a portion of the device isolating layer 25. For example, the current blocking unit 27, e.g., the n⁺ type impurity region 24, may be continuous on the semiconductor substrate 10 to surround the internal circuit region 220, so, e.g., the n⁺ type impurity region 24 and the guard ring 230 may completely overlap each other.

The n⁺ type impurity region 24 may define a reverse junction region of the p-well region 12. In other words, the current blocking unit 27 may be sequentially formed on the semiconductor substrate 10, and may be a reverse junction region including the second region of the p-well region 12 and the n⁺ type impurity region 24 on the p-well region 12. As such, the current blocking unit 27 may block current flow from the guard ring 230 to the semiconductor substrate 10. For example, if the semiconductor device 300 includes a plurality of guard rings 230, the semiconductor device 300 may include a corresponding number of current blocking units 27, so each guard ring 230 may be connect to a separate current blocking unit 27.

More specifically, as an integration degree of the semiconductor device 300 increases, a gap between the internal circuit region 220 and the guard ring 230 along the horizontal direction may decrease. For example, the horizontal distances between the internal routing layers 48, 58, and 68 in the internal circuit region 220 and the respective guard routing layers 50, 60 and 70 in the guard ring 230 may decrease, so the internal routing layers 48, 58, and 68 may be bridged with the guard routing layers 40, 50, 60, and 70, as indicated by a perforated line 202 in FIG. 2. Positioning of the current blocking unit 27 according to an example embodiment may block current flowing from the guard routing layers 40, 50, 60, and 70 and the conductive plugs 34, 44, 54, and 64, i.e., outward, toward the semiconductor substrate 10, even if the internal routing layers 48, 58, and 68 and the guard routing layers 40, 50, 60, and 70 are bridged. As a result, the semiconductor device 300 according to an example embodiment may prevent voltage drop in a standby mode or in an operation mode, e.g., when a voltage of a few volts is applied to the internal routing layers 38, 48, and 58. It is noted that even though FIG. 2 illustrates bridging between the internal routing layer 58 and the guard routing layer 60, the current blocking unit 27 may block a current flow resulting from bridging of any of the internal routing layers and guard routing layers.

In contrast, if a semiconductor device with a guard ring does not include the current blocking unit 27, voltage level of the semiconductor device may drop when any of the internal routing layers is bridged with any of the guard routing layers. For example, connection of a guard ring to a p⁺ impurity region in a p-well region or directly to a substrate, i.e., as opposed to connection to the n⁺ impurity region 24, may cause an electric current flow from the guard routing layers 40, 50, 60, and 70 and the conductive plugs 34, 44, 54, and 64 to the p-well region 12, so the electric current may be discharged or may flow to the semiconductor substrate 10 through the p-well region 12, thereby causing a voltage level may drop. A voltage level drop in semiconductor device at a standby mode or in an operational mode when a voltage of a few volts is applied to the internal routing layers may cause an operational failure of the semiconductor device, i.e., a semiconductor device without the current blocking unit 27.

The semiconductor device 300 may further include a dicing region 240, as illustrated in FIGS. 1-2. The dicing region 240 may be also referred to as a scribe line region. The dicing region 240 may be formed around the guard ring 230, e.g., along a perimeter of the guard ring 230. The dicing region 240 may include a dicing line 250 for cutting a semiconductor wafer, e.g., a silicon wafer, into individual semiconductor devices 300, i.e., semiconductor chips, during fabrication of the semiconductor devices 300. Therefore, the guard ring 230 may prevent formation of cracks in the interlayer insulating layers 30, 36, 42, 46, 52, 56, 62, and 66 of the internal circuit region 220 when the semiconductor wafer is cut along the dicing line 250 to fabricate the individual semiconductor devices 300. Further, as illustrated in FIG. 2, the guard ring 230 may extend along an entire thickness of the internal circuit region 220, i.e., a distance as measured along the vertical direction between an uppermost surface of an uppermost internal routing layer and an uppermost surface of the semiconductor substrate 10, e.g., uppermost surface of the n type impurity region 24, so the guard ring 230 may prevent or substantially minimize diffusion of moisture or impurities into the internal circuit region 220 along an entire thickness thereof.

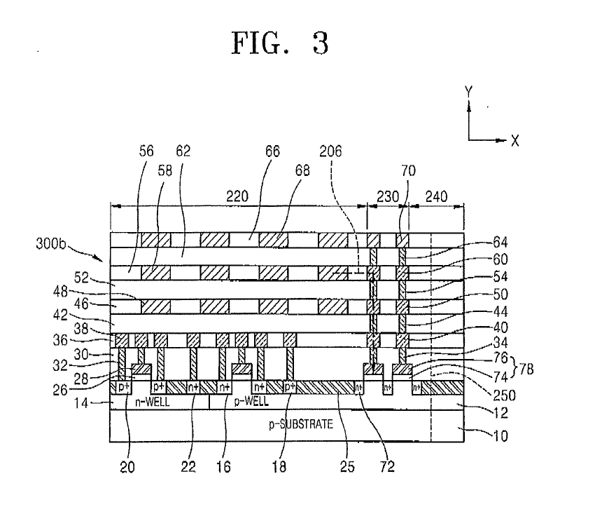

According to another example embodiment illustrated in FIG. 3, a semiconductor device 300b may be substantially the same as the semiconductor device 300 described previously with reference to FIGS. 1-2, with the exception of having the guard ring 230 connected to a gate stack 78.

More specifically, as illustrated in FIG. 3, the gate stack 78 may be formed on the semiconductor substrate 10, and may include a gate insulation layer 74 on the semiconductor substrate 10 and a gate electrode 76 on the gate insulation layer 74. The gate stack 78 may further include n⁺ impurity regions 72 formed in the p-well region 12. The gate insulation layer 74 may be formed, e.g., of an oxide layer, and the gate electrode 76 may be formed, e.g., of a poly-silicon layer doped with impurities. For example, gate stack 78 may be continuous to surround the internal circuit region 220, as discussed previously with reference to the current blocking unit 27.

The guard ring 230 may be connected, e.g., directly connected, to the gate electrode 76. The gate stack 78 may function as the current blocking unit, e.g., the gate insulation layer 74 may block flow of an electric current from the guard ring 230 to the p-well region 12 and/or the semiconductor substrate 10. Therefore, even if the guard routing layer 60 and the internal routing layer 58 are bridged, as illustrated by reference number 206, flow of an electric current from the guard routing layers 40, 50, 60 and 70 and the conductive plugs 34, 44, 54, and 64 to the p-well region 12 and/or the semiconductor substrate 10 may be blocked by the gate stack 78. As a result, the semiconductor device 300b may prevent voltage level drop in a standby mode or an operation mode when a voltage of a few volts is applied to the internal routing layers 48, 58, and 68. For example, if the semiconductor device 300 includes a plurality of guard rings 230, the semiconductor device 300 may include a corresponding number of gate stacks 78, so each guard ring 230 may be connect to a separate gate stack 78.

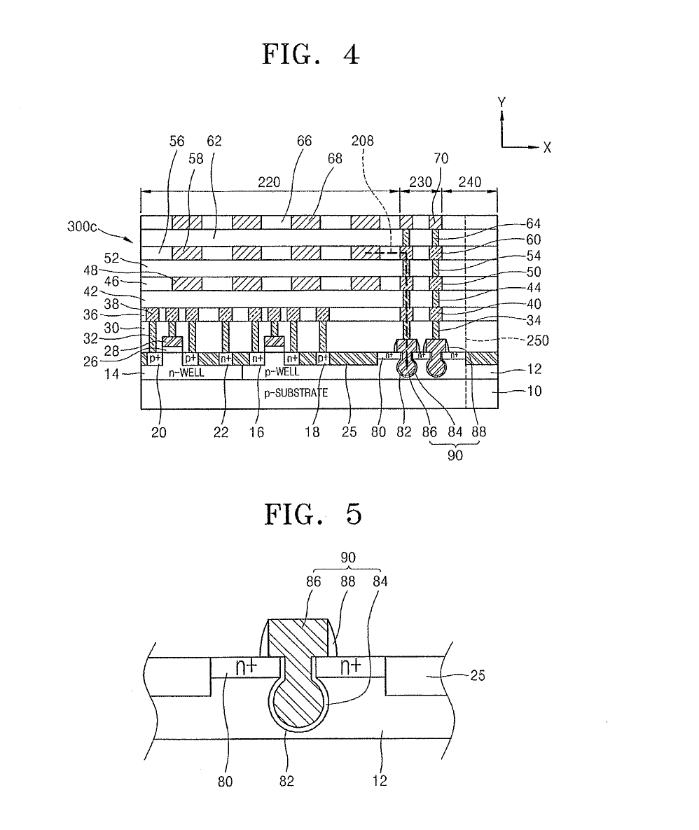

According to another example embodiment illustrated in FIGS. 4-5, a semiconductor device 300c may be substantially the same as the semiconductor device 300b described previously with reference to FIG. 3, with the exception of having a gate stack 90, instead of the gate stack 78, as a current blocking unit. FIG. 4 illustrates a cross sectional view of the semiconductor device 300c, and FIG. 5 illustrates a magnified view of the gate stack 90 shown in FIG. 4.

More specifically, as illustrated in FIGS. 4-5, the gate stack 90 may include a gate insulation layer 84 and a gate electrode 86. The gate insulation layer 84 may be formed in a recess channel trench 82 on the semiconductor substrate 10. The gate electrode 86 may be formed on the gate insulation layer 84 to bury, e.g., completely fill, the recess channel trench 82, so a portion of the gate electrode 86 may extend above the semiconductor substrate 10. The gate stack 90 may further include n⁺ impurity regions 80 formed in the p-well region 12. Spacers 88 may be formed on both sides of the gate electrodes 86 on the semiconductor substrate 10. Alternatively, the spacers 88 may be omitted. The gate insulation layer 84 may be formed of, e.g., an oxide layer, and the gate electrode 86 may be formed of, e.g., a poly-silicon layer doped with impurities. The recess channel trench 82 may have any suitable shape, e.g., circular, vertical rectangle, and so forth.

As illustrated in FIG. 4, the guard ring 230 may be connected to the gate stack 90, e.g., to the gate insulation layer 84, so the gate insulation layer 84 may block current flow therethrough. In other words, the gate stack 90 may function as a current blocking unit. Accordingly, an electric current flowing from the guard routing layers 40, 50, 60, and 70 and the conductive plugs 34, 44, 54, and 64 toward the p-well region 12 or the semiconductor substrate 10, may be blocked by the gate stack 90 even if the internal routing layers 48, 58, and 68 and the guard routing layers 40, 50, 60, and 70 are bridged, e.g., as illustrated by reference numeral 208. As a result, the semiconductor device 300c according to an example embodiment may prevent voltage level drop in the internal routing layers 48, 58, and 68 when the internal routing layers 48, 58, 68 and the guard routing layer 40, 50, 60, and 70 are bridged. For example, if the semiconductor device 300 includes a plurality of guard rings 230, the semiconductor device 300 may include a corresponding number of gate stacks 90, so each guard ring 230 may be connect to a separate gate stack 90.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A semiconductor device, comprising:
an internal circuit region on a semiconductor substrate;
at least one guard ring on the semiconductor substrate, the guard ring surrounding the internal circuit region; and
at least one gate stack on the semiconductor substrate, the gate stack being configured to block an electric current flowing from the guard ring to the semiconductor substrate.

2-7. (canceled)

8. The semiconductor device as claimed in claim 1, wherein the gate stack includes:
a gate insulation layer on the semiconductor substrate; and
a gate electrode on the gate insulation layer.

9. The semiconductor device as claimed in claim 8, wherein the gate insulation layer is in a recess channel trench of the semiconductor substrate.

10-14. (canceled)

15. The semiconductor device as claimed in claim 1, wherein:
the internal circuit includes:
a transistor in a first region of the semiconductor substrate,
at least one interlayer insulating layer on the transistor, and
an internal routing layer in the at least one interlayer insulating layer;
the gate stack is in a second region of the semiconductor substrate, the gate stack surrounding the internal circuit region; and
the guard ring includes:
the interlayer insulating layer on the gate stack,
a guard routing layer in the interlayer insulating layer, the guard routing layer being connected to the gate stack, and
a conductive plug between the guard routing layer and the gate stack.

16. The semiconductor device as claimed in claim 15, wherein the gate stack includes:
a gate insulation layer on the semiconductor substrate; and
a gate electrode on the gate insulation layer.

17. The semiconductor device as claimed in claim 16, wherein the gate insulation layer is in a recess channel trench of the semiconductor substrate.

18. The semiconductor device as claimed in claim 1, wherein the gate stack is electrically connected to the guard ring, the gate stack being between the guard ring and the semiconductor substrate.

19. The semiconductor device as claimed in claim 18, wherein the guard ring is bridged with the internal circuit region.

20. The semiconductor device as claimed in claim 1, wherein the gate stack continuously surrounds the internal circuit region.

21. The semiconductor device as claimed in claim 1, wherein the gate stack and the internal circuit region share a same p-well in the semiconductor substrate.
